(19) United States
(12) Patent Application Publication
(10) Pub. No.: US 2026/0101509 A1
(43) Pub. Date: Apr. 9, 2026

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventor: Doo Hoa CHOI, Icheon-si Gyeonggi-do (KR)

(73) Assignee: SK hynix Inc., Icheon-si Gyeonggi-do (KR)

(21) Appl. No.: 19/062,980

(22) Filed: Feb. 25, 2025

(30) Foreign Application Priority Data
Oct. 7, 2024 (KR) 10-2024-0135850

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device including a substrate including contact regions spaced apart from each other in a first direction, and a guard region positioned between the contact regions, a stack extending from the guard region to the contact regions and including an inclination structure located at a boundary between the guard region and the contact regions, through structures spaced apart from each other in a second direction intersecting the first direction and extending through the inclination structure, and an added structure positioned between the through structures and extending through the inclination structure.

### CROSS-REFERENCE TO RELATED APPLICATION

The present application claims priority under 35 U.S.C. § 119(a) to Korean Patent Application No. 10-2024-0135850 filed on Oct. 7, 2024, in the Korean Intellectual Property Office, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a substrate including contact regions spaced apart from each other in a first direction, and a guard region positioned between the contact regions, a stack extending from the guard region to the contact regions and including an inclination structure located at a boundary between the guard region and the contact regions, through structures spaced apart from each other in a second direction intersecting the first direction and extending through the inclination structure, and an added structure positioned between the through structures and extending through the inclination structure.

According to an embodiment of the present disclosure, a method of manufacturing a semiconductor device may include forming a stack including sacrificial layers on a substrate including contact regions spaced apart from each other in a first direction and a guard region positioned between the contact regions, forming an inclination structure in the stack positioned located at a boundary between the guard region and the contact regions, forming openings spaced apart from each other in a second direction intersecting the first direction and extending through the inclination structure, forming a trench positioned between the openings and extending in the first direction through the inclination structure, forming sacrificial structures in the openings, and forming an added structure in the trench.

### BRIEF DESCRIPTION OF THE DRAWINGS

FIGS. 1A, 1B, 1C, 1D, and 1E are drawings illustrating a semiconductor device according to an embodiment of the present disclosure.

FIGS. 2A, 2B, and 2C are drawings illustrating a semiconductor device according to an embodiment of the present disclosure.

FIGS. 3A, 3B, 4A, 4B, 4C, 4D, and 4E, and 5A, 5B, 5C, 5D, and 5E are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

According to an embodiment of the present technology, a semiconductor device having a stable structure and improved reliability may be provided.

Hereinafter, embodiments according to the technical spirit of the present disclosure are described with reference to the accompanying drawings.

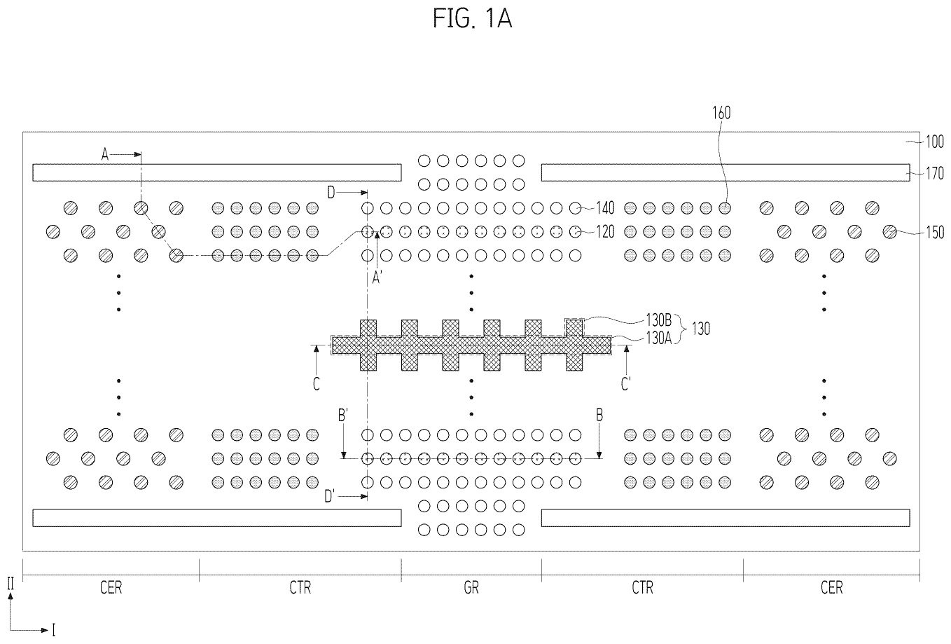

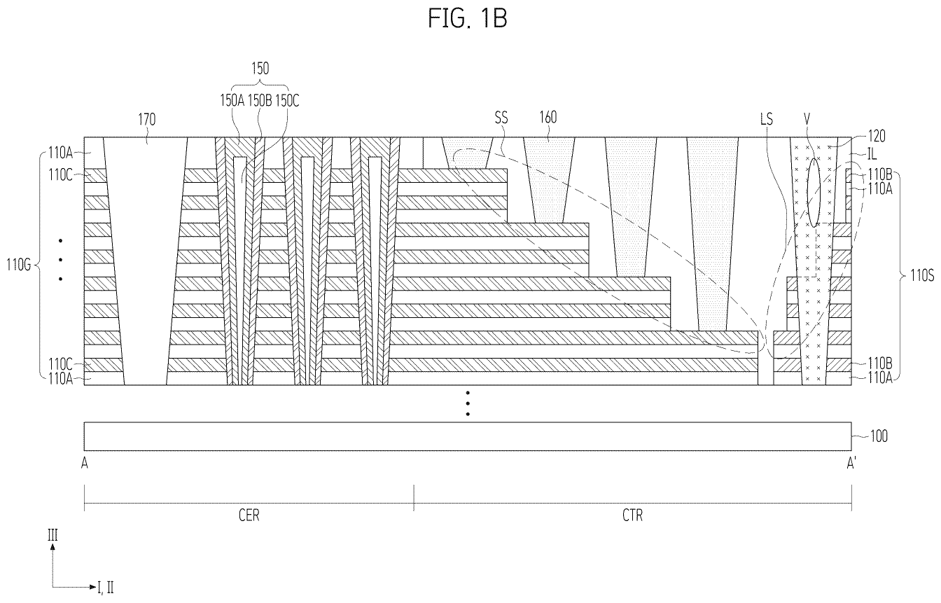

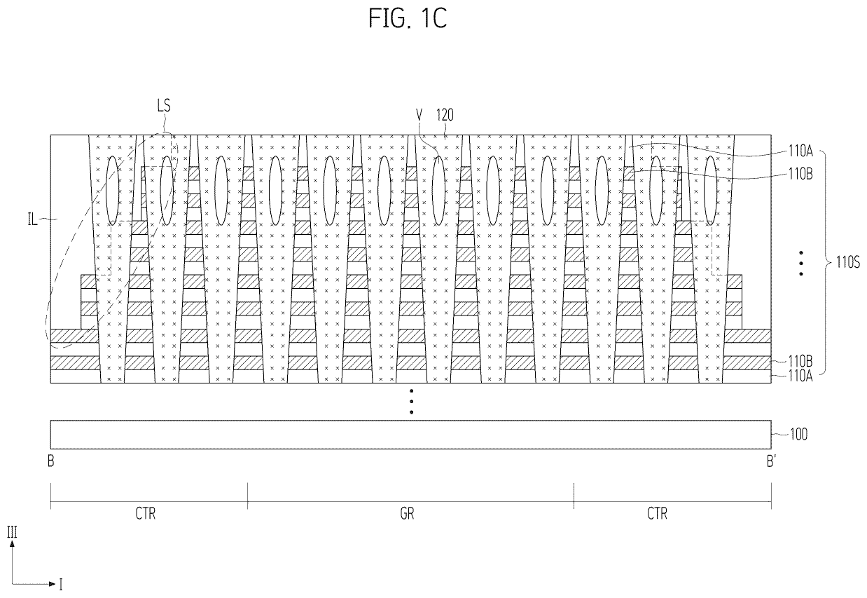

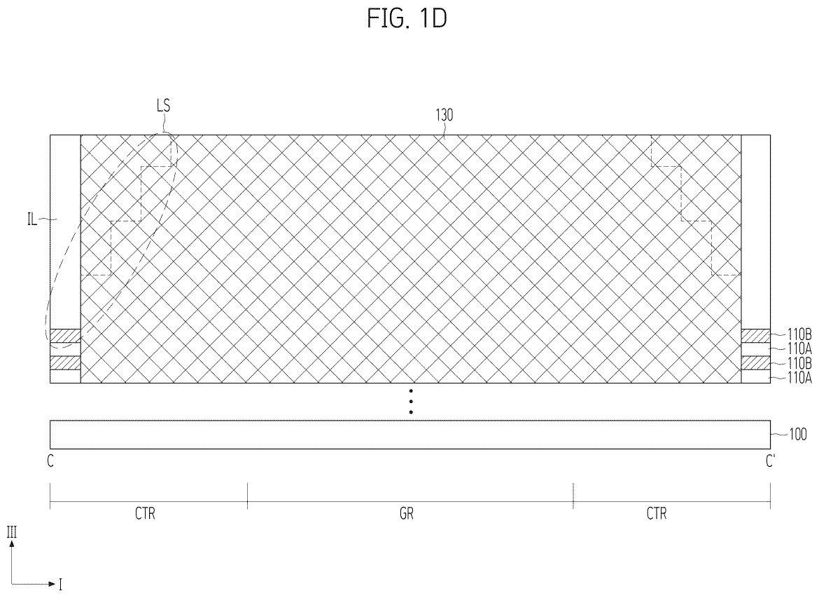

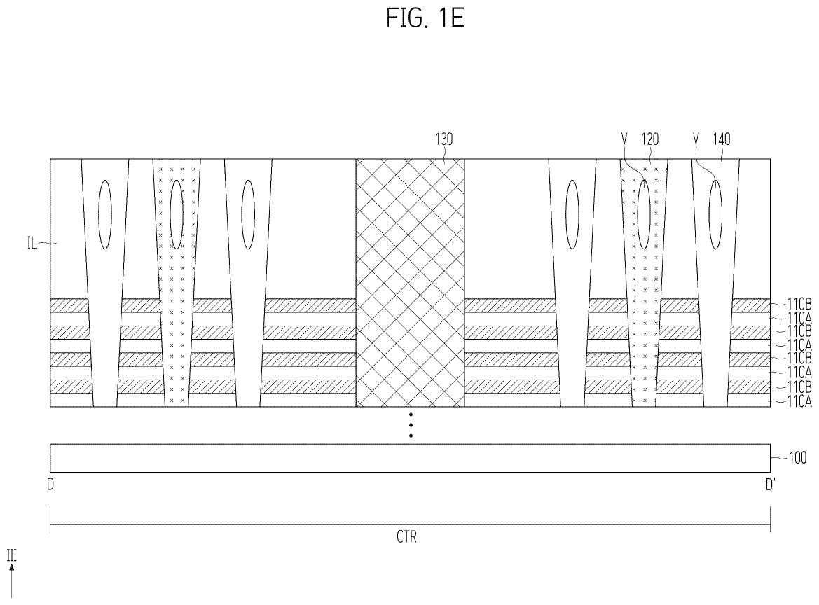

FIGS. 1A to 1E are drawings illustrating a semiconductor device according to an embodiment of the present disclosure. FIG. 1A is a plan view, FIG. 1B is a cross-sectional view taken along line A-A′ of FIG. 1A, FIG. 1C is a cross-sectional view taken along line B-B′ of FIG. 1A, FIG. 1D is a cross-sectional view taken along line C-C′ of FIG. 1A, and FIG. 1E is a cross-sectional view taken along line D-D′ of FIG. 1A.

Referring to FIGS. 1A to 1E, the semiconductor device may include a substrate 100, a stack 110S, a gate structure 110G, through structures 120, an added structure 130, dummy structures 140, channel structures 150, contact vias 160, slit structures 170, and an interlayer insulating layer IL. In an embodiment, an added structure may prevent cracks or mitigate cracks from extending through portions or all of the semiconductor device.

The substrate 100 may include contact regions CTR and a guard region GR. The substrate 100 may further include cell regions CER. The cell region CER may be positioned adjacent to the contact region CTR. The contact regions CTR may be spaced apart from each other in a first direction I. The guard region GR may be positioned between the contact regions CTR. Here, the cell region CER may be a region where memory cells are positioned. The contact regions CTR may be a region where contact vias 160 connected to conductive layers 110C of the gate structure 110G are positioned. The guard region GR may be a region where an added structure 130 is positioned.

The gate structure 110G may be positioned on the substrate 100. The gate structure 110G may extend from the cell region CER to the contact regions CTR. The gate structure 110G may include first insulating layers 110A and the conductive layers 110C alternately stacked. The gate structure 110G may include a step structure SS. The step structure SS may be positioned in the contact region CTR. An upper surface of the conductive layers 110C may contact the interlayer insulating layer IL through the step structure SS. In an embodiment, an upper surface of the conductive layers 110C may face away from the substrate and towards the third direction III. Here, the interlayer insulating layer IL may be positioned on the step structure SS and inclination structure LS.

The conductive layers 110C may be a gate line such as a source selection line, a word line, or a drain selection line. A source selection transistor, a memory cell, or a drain selection transistor may be positioned in a region where the channel structures 150 and the conductive layers 110C intersect. For example, at least one source selection transistor, a plurality of memory cells, and at least one drain selection transistor stacked along a channel structure 150 may configure one memory string. The conductive layers 110C may include a conductive material such as tungsten, molybdenum, or polysilicon. The interlayer insulating layer IL may include an insulating material such as an oxide.

The stack 110S may be positioned on the substrate 100. The stack 110S may extend from the guard region GR to the contact regions CTR. The stack 110S may include first insulating layers 110A and second insulating layers 110B alternately stacked. The second insulating layers 110B may be remains without being replaced by the conductive layers 110C in a process of manufacturing the semiconductor device.

The stack 110S may include an inclination structure LS. Here, the inclination structure LS may have a shape symmetrical to that of the step structure SS. However, the present disclosure is not limited thereto, and the shapes of the inclination structure LS and the step structure SS may be different. The inclination structure LS may have a steep inclination, while the step structure SS may have a gentle inclination compared to the inclination structure LS.

The inclination structure LS may be positioned at the contact regions. the inclination structure LS may be located at the contact regions adjacent to the guard region. For example, the inclination structure LS may be located near a boundary between the guard region GR and the contact regions CTR. Here, a vicinity of the boundary between the guard region GR and the contact regions CTR may mean a region where a portion of the through structures 120 is to be positioned as a certain region facing the contact regions CTR at the boundary between the contact regions CTR and the guard region GR. An upper surface of the second insulating layers 110B may contact the interlayer insulating layer IL through the inclination structure LS. Here, the interlayer insulating layer IL may be positioned on the inclination structure LS. In other words, the interlayer insulating layer IL may be positioned on the inclination structure LS and the step structure SS, and may separate the inclination structure LS and the step structure SS. The first insulating layers 110A and/or the second insulating layers 110B may include an insulating material such as an oxide or a nitride.

The through structures 120 may be positioned in the guard region GR and the contact regions CTR. The through structures 120 may extend through the stack 110S. For example, a portion of the through structures 120 may extend through the inclination structure LS. The through structures 120 may pass through the stack 110S to be connected to a peripheral circuit or the like positioned on the substrate 100.

The through structures 120 may be arranged in the first direction I. For example, the through structures 120 may be arranged in the first direction I from the guard region GR to the contact regions CTR. In addition, the through structures 120 may be spaced apart from each other in a second direction II intersecting the first direction I. The through structures 120 may include a conductive material such as tungsten.

A portion of the through structures 120 may extend through the inclination structure LS of the stack 110S. In other words, in a cross-section defined by the first direction I and a third direction III, one side of the through structures 120 extending through the inclination structure LS may extend through the first and second insulating layers 110A and 110B alternately stacked based on the same level, and another side of the through structures 120 may extend through the interlayer insulating layer IL. That is, the one side and the other side of the through structures 120 may extend through different structures near the boundary between the guard region GR and the contact regions CTR. On the other hand, a portion of the through structures 120 may extend through the stack 110S rather than the inclination structure LS. For example, in the cross-section defined by the first direction I and the third direction III, both of one side and another side of the through structures 120 positioned in the guard region GR may extend through the first and second insulating layers 110A and 110B. Here, the third direction III may mean a direction intersecting the first direction I and the second direction II.

In the vicinity of the boundary between the guard region GR and the contact regions CTR, stress may be concentrated at the boundary because the interlayer insulating layer IL and the inclination structure LS contacting each other. Meanwhile, the through structures 120 may include a void V. In an embodiment, when the through structures 120 extending through the inclination structure LS include the void V, stress may be concentrated on the void V, and a crack may occur while the voids V of the through structures 120 are connected to each other. In other words, in an embodiment, the voids V may be connected between the through structures 120 spaced apart from each other in the second direction II near the boundary between the guard region GR and the contact regions CTR, and thus the crack may occur. In an embodiment, even though the through structures 120 extending through the stack 110S rather than the inclination structure LS include the void V, stress might not be concentrated on the void V, and a crack might not occur.

The added structure 130 may be positioned in the guard region GR and the contact regions CTR. The added structure 130 may be positioned between the through structures 120. For example, the added structure 130 may be positioned between the through structures 120 spaced apart from each other in the second direction II. The added structure 130 may extend through the stack 110S. For example, the added structure 130 may extend through the inclination structure LS of the stack 110S.

The added structure 130 may include a first portion 130A and second portions 130B. Here, the first portion 130A may extend in the first direction I from the guard region GR to the contact regions CTR. The second portions 130B may protrude from the first portion 130A. For example, the second portions 130B may protrude in the second direction II from the first portion 130A. The added structure 130 might not include a void. The added structure 130 may include an insulating material such as an oxide.

According to an embodiment of the present disclosure, the added structure 130 may be positioned between the through structures 120 spaced apart from each other in the second direction II. Here, the added structure 130 may have a line shape extending in the first direction I from the guard region GR to the contact regions CTR. In other words, the added structure 130 of the line shape extending in the first direction I may be positioned between the through structures 120 positioned adjacent to each other in the second direction II. In an embodiment, even though a crack occurs in a portion of the through structures 120, the crack may be prevented from or mitigated from propagating in the second direction II through the added structure 130.

The dummy structures 140 may be positioned in the guard region GR and the contact regions CTR. The dummy structures 140 may extend through the stack 110S. For example, a portion of the dummy structures 140 may extend through the inclination structure LS. The dummy structures 140 may be disposed around the through structures 120. For example, the dummy structures 140 may be arranged in the first direction I from the guard region GR to the contact regions CTR. In an embodiment, the dummy structures 140 may be used as a support. The dummy structures 140 may include an insulating material such as an oxide.

The dummy structures 140 may include a void V. However, the present disclosure is not limited thereto, and the dummy structures 140 might not include a void V. In an embodiment, when the dummy structures 140 include the void V, the void V of the dummy structures 140 may be used as a path through which the crack occurring in the through structures 120 propagates in the second direction II. However, even in this case, in an embodiment, crack propagation may be prevented or minimized by the added structure 130.

The channel structure 150 may be positioned in the cell region CER and may extend through the gate structure 110G gate structure 110G. The channel structure 150 may include a channel layer 150A and a memory layer 150B. The channel structure 150 may further include an insulating core 150C. Here, the memory layer 150B may surround the channel layer 150A. The insulating core 150C may be positioned in the channel layer 150A.

The contact vias 160 may be positioned in the contact region CTR and may be connected to the conductive layers 110C. For example, the contact vias 160 may extend through the interlayer insulating layer IL to be connected to the upper surface of the conductive layers 110C. The contact vias 160 may include a conductive material such as tungsten.

The slit structure 170 may extend from the cell region CER to the contact region CTR and may extend through the gate structure 110G. The slit structure 170 may include an insulating material, a conductive material, a semiconductor material, or the like.

According to an embodiment of the structure described above, the semiconductor device may include the added structure 130 of the line shape extending in the first direction I between the through structures 120 spaced apart from each other in the second direction II near the boundary between the guard region GR and the contact regions CTR. In this case, in an embodiment, even though the through structures 120 have a relatively unstable structure by extending through the inclination structure LS of the stack 110S, occurrence of a crack may be prevented or reduced by connecting the voids V of the through structures 120.

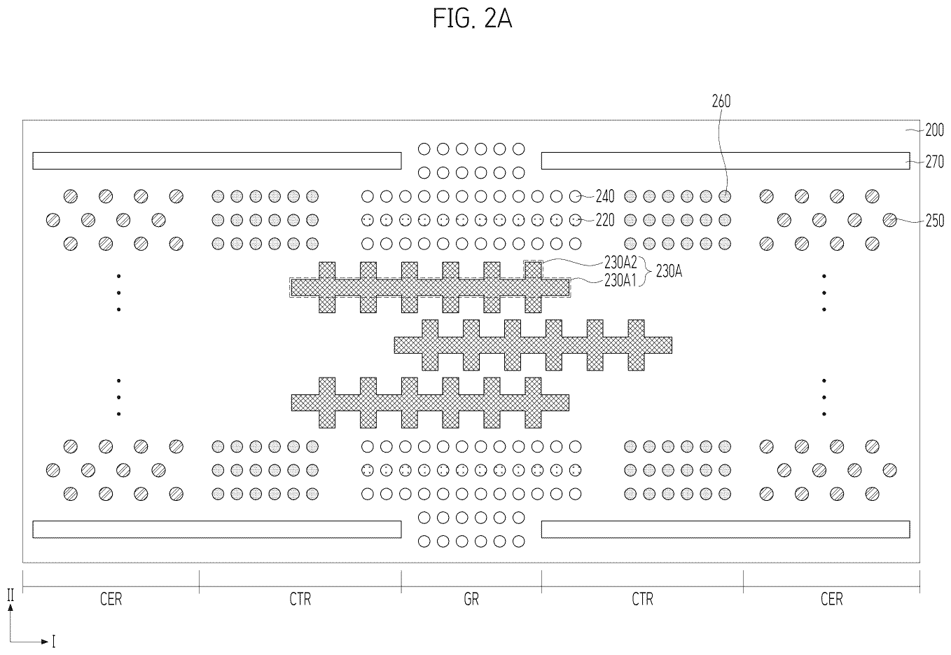

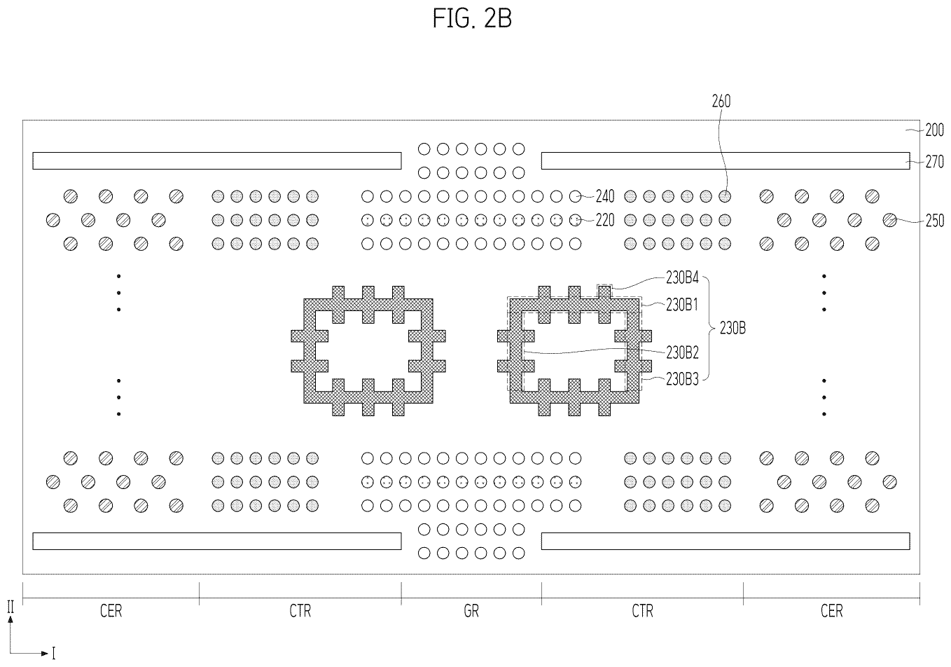

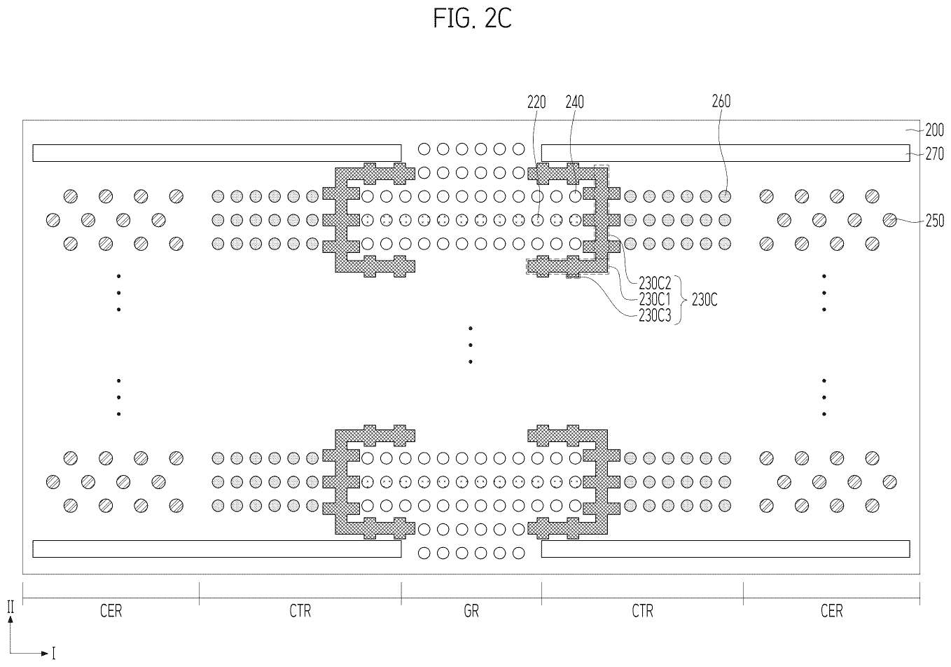

FIGS. 2A to 2C are drawings illustrating a semiconductor device according to an embodiment of the present disclosure. FIGS. 2A to 2C are plan views. Hereinafter, content that overlaps the content described above is omitted.

Referring to FIGS. 2A to 2C, the semiconductor device may include a substrate 200, through structures 220, added structures 230A, 230B, and 230C, dummy structures 240, channel structures 250, contact vias 260, and slit structures 270.

The substrate 200 may include cell regions CER, contact regions CTR, and a guard region GR. The cell region CER may be positioned adjacent to the contact region CTR. The contact regions CTR may be spaced apart from each other in a first direction I. The guard region GR may be positioned between the contact regions CTR. Here, the cell region CER may be a region where memory cells are positioned. The contact regions CTR may be a region where contact vias 260 are positioned. The guard region GR may be a region where the added structure 230A is positioned. In an embodiment, the added structure 230A may be positioned in the guard region GR and the contact region CTR.

The through structures 220 may be positioned in the guard region GR and the contact regions CTR. The through structures 220 may be arranged in the first direction I from the guard region GR to the contact regions CTR. In addition, the through structures 220 may be spaced apart from each other in a second direction II intersecting the first direction I. The through structures 220 may include a void. The through structures 220 may include a conductive material such as tungsten.

The dummy structures 240 may be disposed around the through structures 220. For example, the dummy structures 240 may be arranged in the first direction I from the guard region GR to the contact regions CTR. The dummy structures 240 may include a void. However, the present disclosure is not limited thereto, and the dummy structures 240 might not include a void. The dummy structures 240 may include an insulating material such as an oxide.

The channel structures 250 may be positioned in the cell region CER. The channel structures 250 may include a channel layer, a memory layer surrounding the channel layer, and an insulating core in the channel layer. The contact vias 260 may be positioned in the contact region CTR. The contact vias 260 may include a conductive material such as tungsten. The slit structures 270 may extend in the first direction I from the cell region CER to the contact region CTR. The slit structure 270 may include an insulating material, a conductive material, a semiconductor material, or the like.

Referring to FIG. 2A, the added structure 230A may have a shape similar to that of the added structure 130 of FIG. 1A. For example, the added structure 230A may include a first portion 230A1 of a line shape and may include second portions 230A2 protruding from the first portion 230A. For example, the added structure 230A may include a first portion 230A1 extending in a first direction I and may include second portions 230A2 protruding from the first portion 230A in the second direction II. In an embodiment, the second portions 230A2 may be spaced apart from each other. In an embodiment, the second portions 230A2 might not be spaced apart from each other.

In addition, two or more added structures 230A may be disposed. For example, one added structure 230A may extend from the guard region GR to one of the contact regions CTR, and one added structure 230A may extend from the guard region GR to a remaining contact region CTR. However, the present disclosure is not limited thereto, and each added structure 230A may also extend from the guard region GR to the contact regions CTR.

Therefore, according to an embodiment of the present disclosure, by disposing a plurality of added structures 230A between the through structures 220 spaced apart from each other in the second direction II, even though a crack propagates through one added structure 230A, the crack may be prevented or mitigated from propagating through the remaining added structures 230A.

Referring to FIG. 2B, the added structure 230B may have a shape different from that of the added structure 230A of FIG. 2A. For example, the added structure 230B may have a closed curve shape. For example, the added structure 230B may have a closed loop shape as shown in FIG. 2B. For example, the added structure 230B may have a square or rectangle shape as shown in FIG. 2B. The added structure 230B may include first portions 230B1 extending in the first direction I from the guard region GR to one of the contact regions CTR, second portions 230B2 extending in the second direction II from the guard region GR to connect the first portions 230B1, and third portions 230B3 extending in the second direction II from one of the contact regions CTR to connect the first portions 230B1.

In addition, two or more added structures 230B may be disposed. For example, the added structures 230B may be spaced apart from each other in the first direction I, and may be respectively positioned between the through structures 220 spaced apart from each other in the second direction II. That is, in an embodiment, because a crack occurs relatively less in the guard region GR than in the vicinity of the boundary between the guard region GR and the contact regions CTR, the added structures 230B may be positioned only in the vicinity of the boundary between the guard region GR and the contact regions CTR. In this case, in an embodiment, a crack may be prevented or mitigated from being propagated by disposing the first portions 230B1 in a double or more manner on a path through which the crack may propagate.

In an embodiment, the added structure 230B may include fourth portions 240B4 protruding from the first portions 230B1, the second portion 230B2, and the third portion 230B3. Here, the fourth portions 240B4 may protrude in the first direction I or the second direction II. In an embodiment, the fourth portions 230B4 may be spaced apart from one another. In an embodiment, the fourth portions 230B4 might not be spaced apart from one another.

Referring to FIG. 2C, the added structure 230C may have a shape different from that of the added structures 230A and 230 of FIGS. 2A and 2B. For example, the added structure 230C may have a C shape. In an embodiment the added structure 230C may have semicircle shape. In an embodiment the added structure 230C may have semicircle shape that include one or more right angle shapes as, for example, shown in FIG. 2C. In an embodiment the added structure 230C may have a shape that includes one or more angles, for example, the shape shown in FIG. 2C. In an embodiment, the added structure 230C may include at least one segment including a curve or an angle as, for example, shown in FIG. 2C. In an embodiment, the added structure 230C may form an incomplete or open perimeter as shown in, for example, FIG. 2C. In other embodiments, the added structure may have a shape different from what is shown in FIG. 2C. The added structure 230C may include first portions 230C1 extending in the first direction I from the guard region GR to one of the contact regions CTR, and second portions 230C2 extending in the second direction II from one of the contact regions CTR to connect the first portions 230C1.

The added structure 230C may be disposed to surround a periphery of the through structures 220. For example, the added structure 230C may be disposed so that a portion of the through structures 220 may be positioned in an open region of the added structure 230C. In this case, the crack through which voids between the through structures 220 are connected may be prevented or mitigated, the crack occurring in the through structures 220 may be prevented or minimized from propagating to other structures such as the slit structure 270.

In addition, two or more added structures 230C may be disposed. The added structures 230C may include third portions 230C3 protruding from the first portions 230C1 and the second portion 230C2. Here, the third portions 230C3 may protrude in the first direction I or the second direction II. In an embodiment, the third portions 230C3 may be spaced apart from one another. In an embodiment, the third portions 230C3 might not be spaced apart from one another.

According to the structure described above, the added structures 230A, 230B, and 230C may have various modified examples. However, the present disclosure is not limited thereto, and the added structures may be variously modified into structures for preventing the cracks occurring in the through structures 220 from propagating in the second direction II, near the boundary between the guard region GR and the contact regions CTR. For example, the added structures may be positioned between the through structures 220 spaced apart from each other in the second direction II, and may be modified to include a portion extending from the guard region GR to the contact regions CTR.

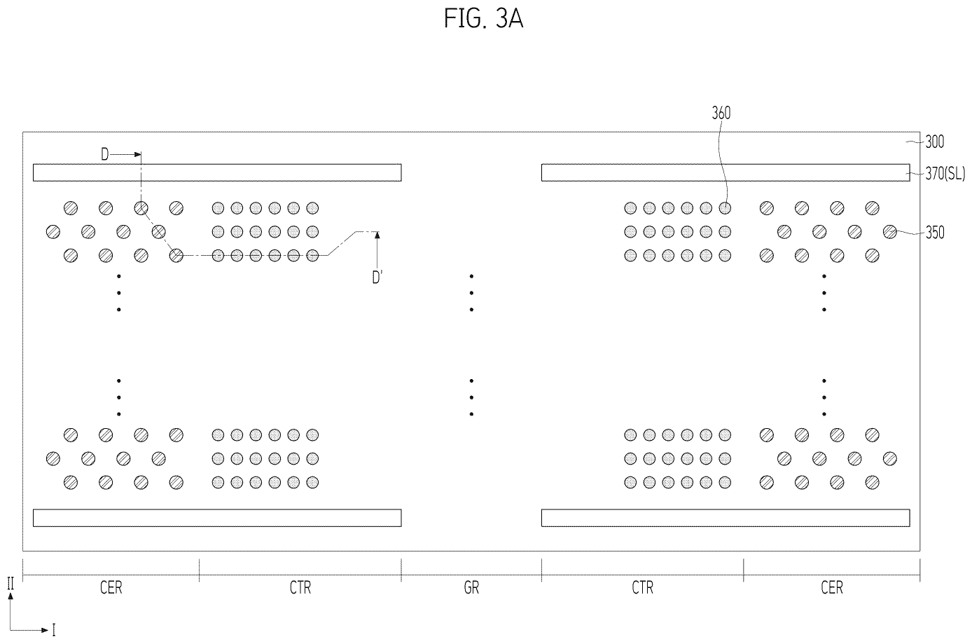

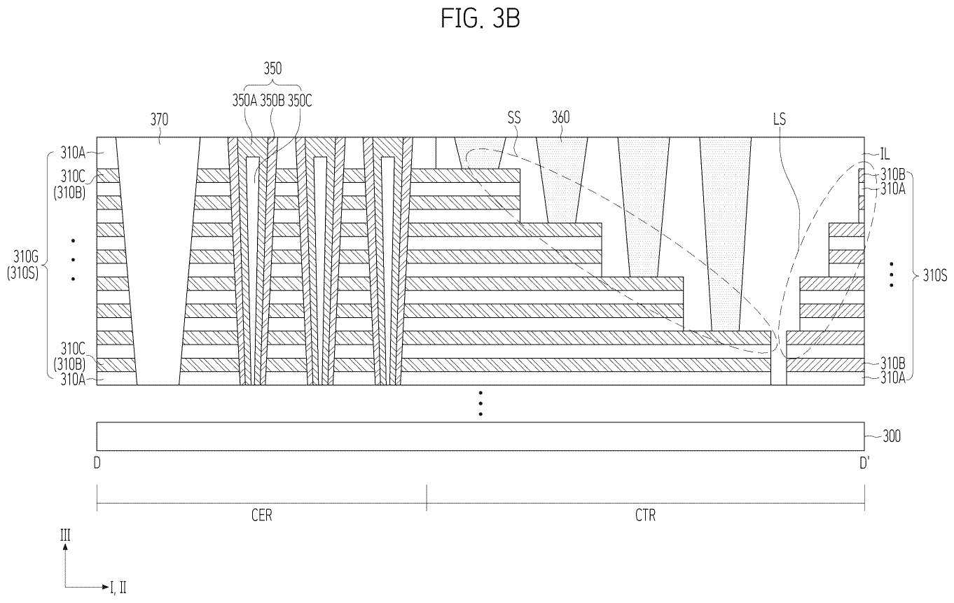

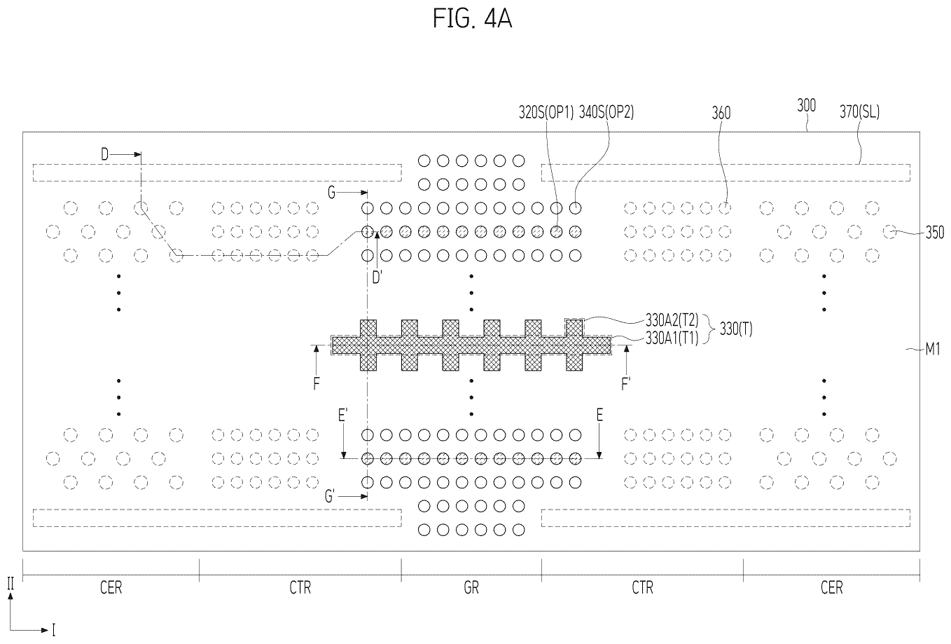

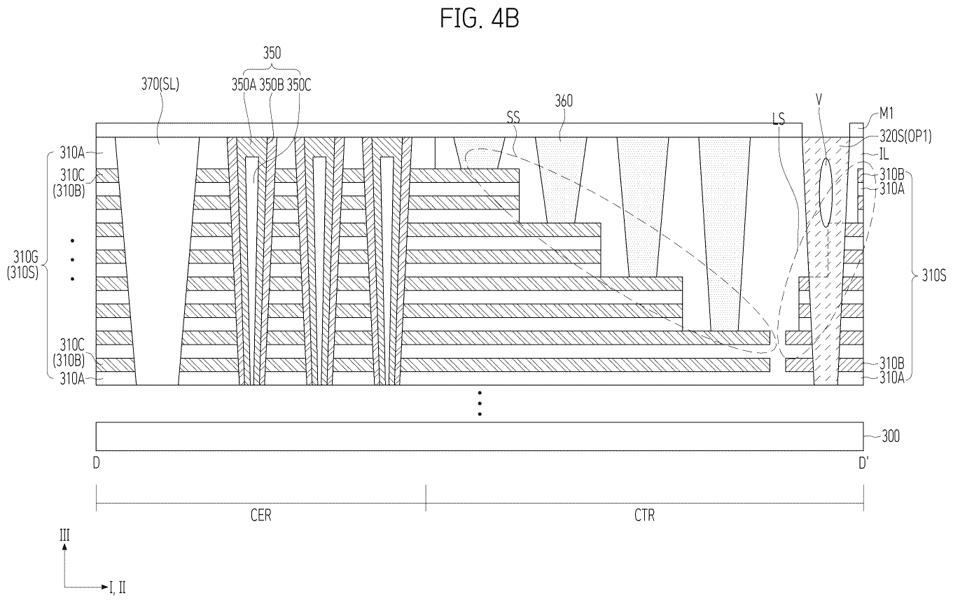

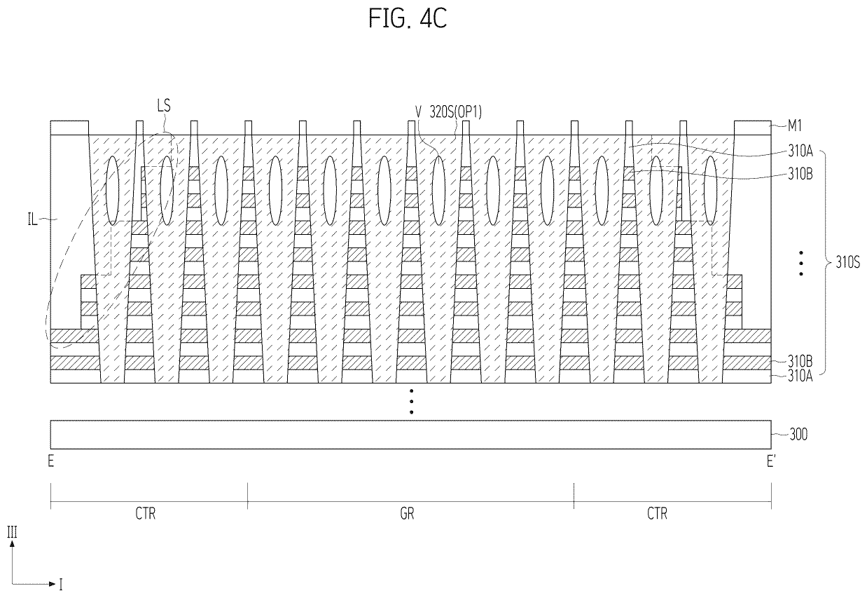

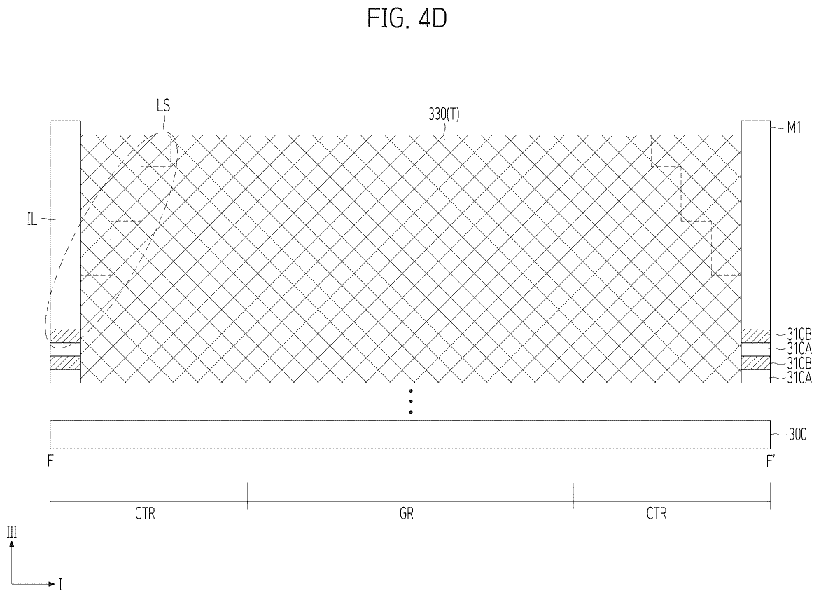

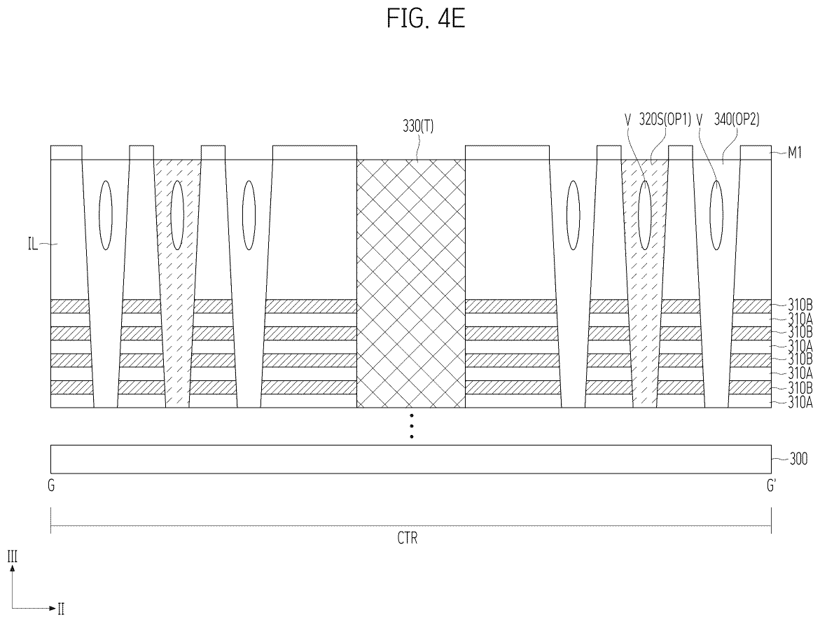

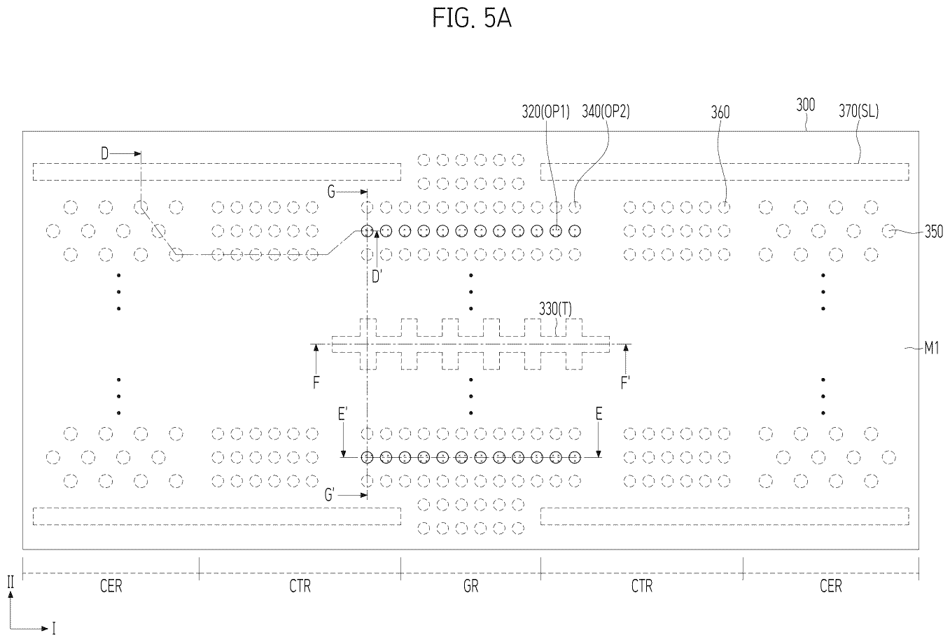

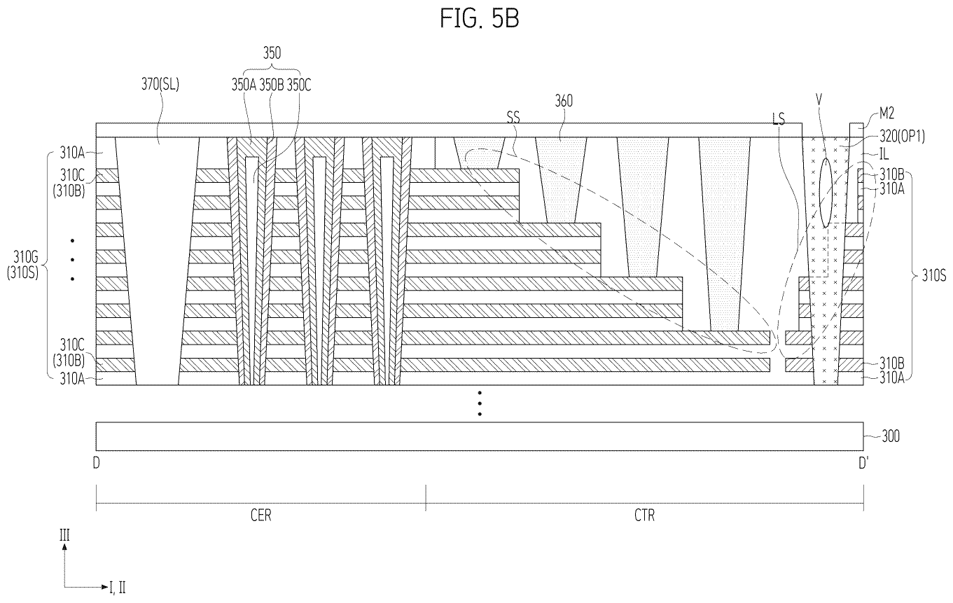

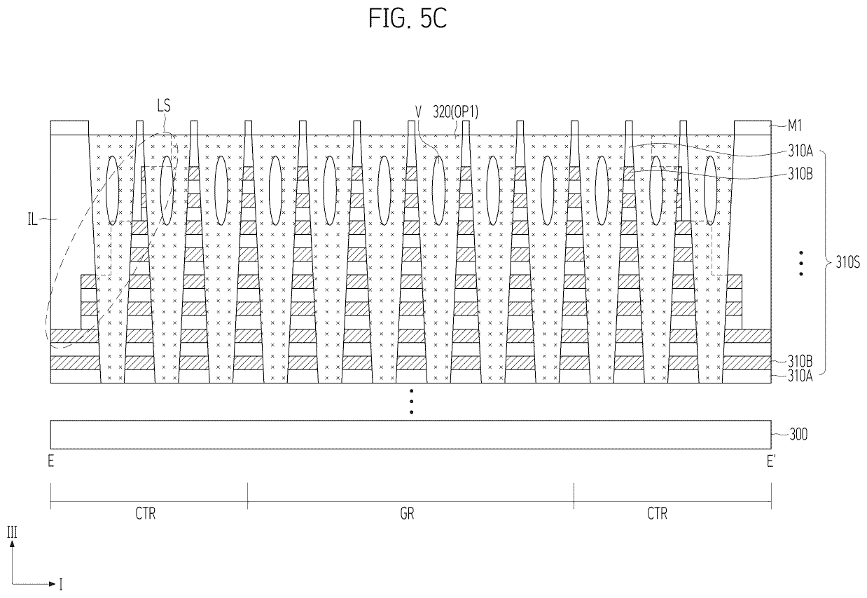

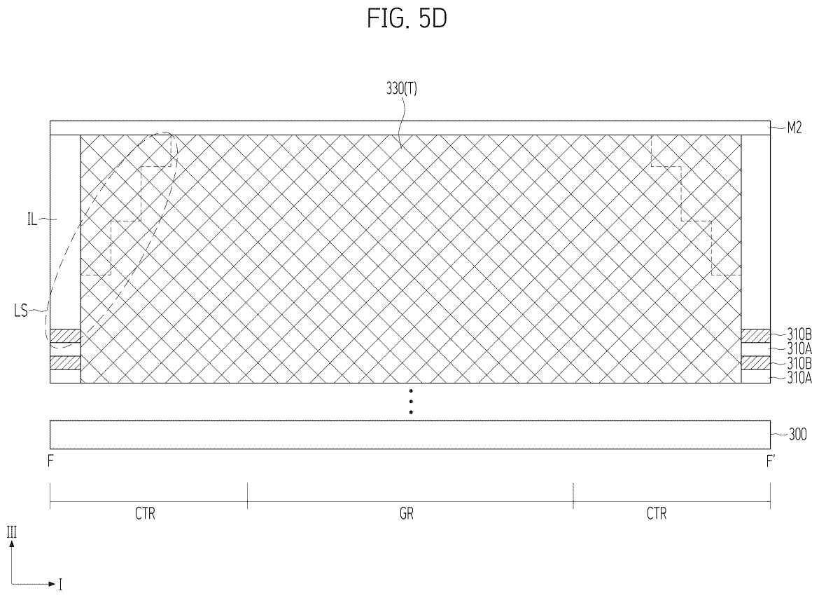

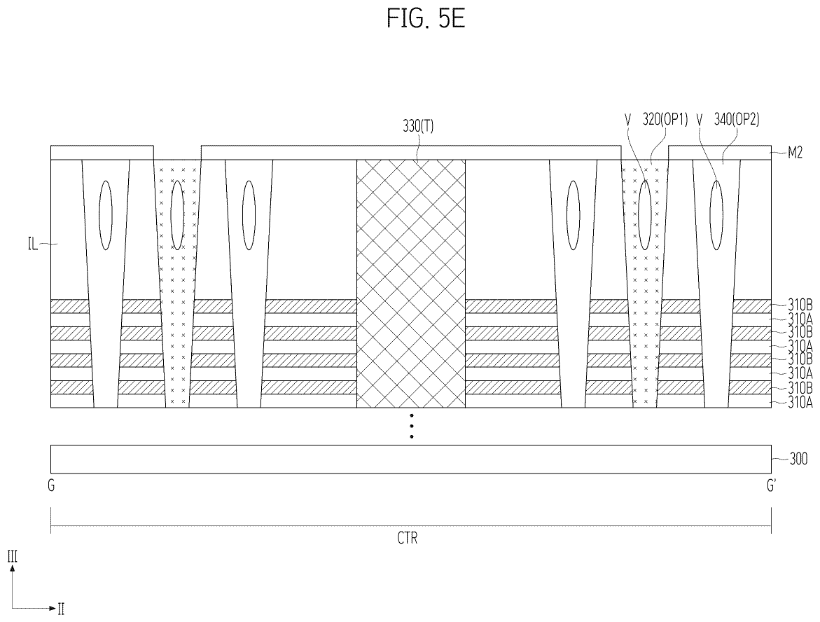

FIGS. 3A, 3B, 4A to 4E, and 5A to 5E are drawings illustrating a method of manufacturing a semiconductor device according to an embodiment of the present disclosure. FIGS. 3A, 4A, and 5A are plan views, FIGS. 3B and 4B are cross-sectional views taken along line D-D′ of each of FIG. A, FIGS. 4B and 5B are cross-sectional views taken along line E-E′ of each of FIG. A, FIGS. 4D and 5D are cross-sectional views taken along line F-F′ of each of FIG. A, and FIGS. 4E and 5E are cross-sectional views taken along line G-G′ of each of FIG. A. Hereinafter, content that overlaps the content described above is omitted.

Referring to FIGS. 3A and 3B, a stack 310S may be formed on a substrate 300. For example, insulating layers 310A and sacrificial layers 310B may be alternately stacked on the substrate 300 to form the stack 310S. Here, the insulating layers 310A may include an insulating material such as an oxide. The sacrificial layers 310B may include a sacrificial material such as a nitride.

Meanwhile, the substrate 300 may include contact regions CTR and a guard region GR. The substrate 300 may further include cell regions CER. The cell region CER may be positioned adjacent to the contact region CTR. The contact regions CTR may be spaced apart from each other in a first direction I. The guard region GR may be positioned between the contact regions CTR. Here, the cell region CER may be a region where memory cells are to be formed. The contact regions CTR may be a region where contact vias 360 connected to conductive layers 310C of a gate structure 310G are to be formed. The guard region GR may be a region where an added structure is to be formed.

Subsequently, channel structures 350 extending through the stack 310S may be formed. Here, the channel structures 350 may be formed in the cell region CER. Each of the channel structures 350 may include a channel layer 350A and a memory layer 350B surrounding the channel layer 350A. Each of the channel structures 350 may further include an insulating core 350C in the channel layer 350A.

A step structure SS may be formed in the stack 310S. For example, the step structure SS exposing the sacrificial layers 310B may be formed in the stack 310S positioned in the contact regions CTR.

An inclination structure LS may be formed in the stack 310S. For example, the inclination structure LS may be formed in the stack 310S positioned near the boundary between the guard region GR and the contact regions CTR. Here, a vicinity of the boundary between the guard region GR and the contact regions CTR may mean a region where a portion of through structures is to be formed as a certain region facing the contact regions CTR at the boundary between the contact regions CTR and the guard region GR.

The inclination structure LS is formed over a first interval of time and the step structure SS are formed over a second interval of time, the first and second intervals of time at least partially overlapping each other. For example, when forming the step structure SS, the inclination structure LS may be formed. However, the present disclosure is not limited thereto, and a timing for forming the step structure SS and the inclination structure LS may be different. The sacrificial layers 310B may be exposed through the inclination structure LS.

The inclination structure LS may have a shape symmetrical to that of the step structure SS. However, the present disclosure is not limited thereto, and the shapes of the inclination structure LS and the step structure SS may be different. The inclination structure LS may have a steep inclination, while the step structure SS may have a gentle inclination compared to the inclination structure LS.

Subsequently, an interlayer insulating layer IL may be formed. For example, the interlayer insulating layer IL may be formed on the step structure SS and the inclination structure LS. The interlayer insulating layer IL may separate the inclination structure LS and the step structure SS. The interlayer insulating layer IL may include an insulating material such as an oxide.

A slit SL extending through the stack 310S may be formed. For example, the slit SL extending in the first direction I may be formed. Here, the slit SL may extend from the cell region CER to the contact region CTR. Subsequently, the sacrificial layers 310B may be replaced with conductive layers 310C through the slit SL. For example, the sacrificial layers 310B of the stack 310S positioned in the cell region CER and the contact regions CTR may be replaced with the conductive layers 310C. Here, the stack 310S positioned in the contact regions CTR may mean the stack 310S including the step structure SS. First, openings may be formed by removing the sacrificial layers 310B through the slit SL. Subsequently, the conductive layers 310C may be formed in the openings. Here, the conductive layers 310C may be used as a gate line. Accordingly, the gate structure 310G in which the insulating layers 310A and the sacrificial layers 310C are alternately stacked may be formed. Subsequently, slit structures 370 may be formed in the slit SL. The slit structures 370 may include an insulating material, a conductive material, a semiconductor material, or the like.

Contact vias 360 may be formed in the contact regions CTR. For example, the contact vias 360 extending through the interlayer insulating layer IL to be connected to an upper surface of the conductive layers 310C may be formed. The contact vias 360 may include a conductive material such as tungsten.

For reference, a timing for forming the slit SL, the slit structure 370, and the contact vias 360 may be changed. For example, the contact vias 360 may be formed first before forming the slit SL and the slit structure 370. In this case, the contact vias 360 contacting an upper surface of the sacrificial layers 310B of the stack 310S may be formed in the contact regions CTR.

Referring to FIGS. 4A to 4E, a first mask pattern M1 may be formed. For example, the first mask pattern M1 may be formed on the gate structure 310G, the interlayer insulating layer IL, and the stack 310S. Here, the first mask pattern M1 may cover a region corresponding to the gate structure 310G and expose a portion of a region corresponding to the stack 310S. In particular, the guard region GR and a portion near the boundary between the guard region GR and the contact regions CTR may be exposed.

Subsequently, first openings OP1 may be formed by etching the stack 310S using the first mask pattern M1 as an etching barrier. For example, the first openings OP1 may be formed in the contact regions CTR and the guard region GR. Here, the first openings OP1 may be formed to be arranged in the first direction I. In addition, the first openings OP1 may be formed spaced apart from each other in a second direction II intersecting the first direction I. In addition, the first openings OP1 may be formed to extend through the inclination structure LS.

A trench T may be formed using the first mask pattern M1 as an etching barrier. For example, the trench T may be formed by etching the stack 310S using the first mask pattern M1 as an etching barrier. The trench T is formed over a first interval of time and the first openings OP1 are formed over a second interval of time, the first and second intervals of time at least partially overlapping each other. For example, when forming the first openings OP1, the trench T may be formed. Here, the trench T may be formed to be positioned between the first openings OP1 spaced apart from each other in the second direction II. For example, the trench T may be positioned between the first openings OP1 and may extend in the first direction I through the inclination structure LS.

The trench T may include a first portion T1 extending in the first direction I from the guard region GR to the contact regions CTR and second portions T2 protruding from the first portion T1. Here, the second portions T2 may protrude in the second direction II.

For reference, although not shown in the drawing, the trench T may be formed to have a shape and/or an arrangement of the added structures 240A, 240B, and 240C of FIGS. 2A to 2C. For example, a plurality of trenches may be formed, and one of the trenches may extend from the guard region GR to one of the contact regions CTR, and another trench may extend from the guard region GR to a remaining contact region CTR. However, the present disclosure is not limited thereto, and each of the trenches may extend from the guard region GR to the contact regions CTR.

As another example, the trench T may have a closed curve shape. The trench T may include first portions extending in the first direction I from the guard region GR to one of the contact regions CTR, a second portion extending in the second direction II from the guard region GR to connect the first portions, and a third portion extending in the second direction II from one of the contact regions CTR to connect the first portions. The trench T may further include fourth portions protruding from the first portions, the second portion, and the third portion. Here, the fourth portions may protrude in the first direction I or the second direction II.

As still another example, the trench T may have a C shape. The trench T may include first portions extending in the first direction I from the guard region GR to one of the contact regions CTR and second portions extending in the second direction II from one of the contact regions CTR to connect the first portions. The trench T may include third portions protruding from the first portions and the second portion. Here, the third portions 230C3 may protrude in the first direction I or the second direction II.

Second openings OP2 may be formed using the first mask pattern M1 as an etching barrier. When forming the first openings OP1, the second openings OP2 may be formed. The second openings OP2 may be positioned in the guard region GR and the contact regions CTR. The second openings OP2 may be formed to be disposed around the first openings OP1. For example, the second openings OP2 may be formed to be arranged in the first direction I from the guard region GR to the contact regions CTR.

Subsequently, sacrificial structures 320S may be formed in the first openings OP1. The sacrificial structures 320S may include a sacrificial material such as tungsten, oxide, or polysilicon.

A added structure 330 may be formed in the trench T. The added structure 330 is formed over a first interval of time and the sacrificial structures 320S are formed over a second interval of time, the first and second intervals of time at least partially overlapping each other. For example, when forming the sacrificial structures 320S, the added structure 330 may be formed. However, the present disclosure is not limited thereto, and a timing for forming the sacrificial structures 320S and the added structure 330 may be different. The added structure 330 might not include a void. The added structure 330 may include an insulating material such as an oxide.

Dummy structures 340 may be formed in the second openings OP2. When forming the sacrificial structures 320S, the dummy structures 340 may be formed. However, the present disclosure is not limited thereto, and the timing for forming the sacrificial structures 320S and the dummy structures 340 may be different. The dummy structures 340 may include a void V. However, the present disclosure is not limited thereto, and the dummy structures 340 might not include a void V. Here, the dummy structures 340 may be used as a support in a process of manufacturing the semiconductor device. The dummy structures 340 may include an insulating material such as an oxide.

Subsequently, the first mask pattern M1 may be removed.

Referring to FIGS. 5A to 5E, a second mask pattern M2 may be formed. For example, the second mask pattern M2 may be formed on the gate structure 310G, the interlayer insulating layer IL, and the stack 310S. Here, the second mask pattern M2 may cover a region corresponding to the gate structure 310G and expose a portion of a region corresponding to the stack 310S. In particular, the second mask pattern M2 may expose the sacrificial structures 320S formed in the first openings OP1.

Subsequently, the first openings OP1 may be reopened using the second mask pattern M2 as an etching barrier. For example, the first openings OP1 may be reopened by removing the sacrificial structures 320S using the second mask pattern M2 as an etching barrier. Subsequently, through structures 320 may be formed in the first openings OP1. Here, the through structures 320 may include a void V.

Subsequently, the second mask pattern M2 may be removed.

In an embodiment, a portion of the through structures 320 may extend through the inclination structure LS of the stack 310S near the boundary between the guard region GR and the contact regions CTR. Because the interlayer insulating layer IL and the inclination structure LS contact with each other near the boundary between the guard region GR and the contact regions CTR, stress may be concentrated at the boundary. In an embodiment, the through structures 320 may include a void V. In an embodiment, when the through structures 320 extending through the inclination structure LS include the void V, stress may be concentrated at the void V, and a crack may occur while the voids V of the through structures 320 spaced apart from each other in the second direction II are connected to each other.

According to an embodiment of the present disclosure, the added structure 330 may be formed between the through structures 320 spaced apart from each other in the second direction II, and may have a line shape extending in the first direction I from the guard region GR to the contact regions CTR. The added structure 330 may extend through the inclination structure LS of the stack 310S. In this case, in an embodiment, even though a crack occurs in a portion of the through structures 320, the crack may be prevented or mitigated from propagating in the second direction II through the added structure 330.

According to an embodiment of the manufacturing methods described above, the added structure 330 of the line shape extending in the first direction I from the garden region GR to the contact regions CTR may be formed. Through this, in an embodiment, even though a crack occurs in the through structures 320 spaced apart from each other in the second direction II, the crack may be prevented or mitigated from propagating in the second direction II.

In addition, in an embodiment, when forming the first openings OP1, the trench T may be formed. In other words, in an embodiment, a process of forming different structures may be unified, and a manufacturing cost of the semiconductor device may be reduced.

Although embodiments according to the technical spirit of the present disclosure have been described with reference to the accompanying drawings, this is only for describing an embodiment according to the concept of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a substrate including contact regions spaced apart from each other in a first direction, and a guard region positioned between the contact regions;
a stack extending from the guard region to the contact regions and including an inclination structure located at the contact regions adjacent to the guard region;
through structures spaced apart from each other in a second direction intersecting the first direction and extending through the inclination structure; and
an added structure positioned between the through structures and extending through the inclination structure.

2. The semiconductor device of claim 1, wherein the added structure includes a first portion extending in the first direction from the guard region to the contact regions.

3. The semiconductor device of claim 2, wherein the added structure further includes second portions protruding from the first portion.

4. The semiconductor device of claim 1, wherein the added structure includes a closed curve shape.

5. The semiconductor device of claim 4, wherein the added structure includes first portions extending in the first direction from the guard region to one of the contact regions, a second portion extending from the guard region in the second direction to connect the first portions, and a third portion extending in the second direction from one of the contact regions to connect the first portions.

6. The semiconductor device of claim 5, wherein the added structure further includes fourth portions protruding from the first portions, the second portion, and the third portion.

7. The semiconductor device of claim 1, wherein the added structure has a shape including one or more angles.

8. The semiconductor device of claim 7, wherein the added structure includes first portions extending in the first direction from the guard region to one of the contact regions, and a second portion extending in the second direction from one of the contact regions to connect the first portions.

9. The semiconductor device of claim 8, wherein the added structure further includes third portions protruding from the first portions and the second portions.

10. The semiconductor device of claim 1, wherein the added structure includes an insulating material.

11. The semiconductor device of claim 10, wherein the added structure includes an oxide.

12. The semiconductor device of claim 1, wherein each of the through structures includes a void, and wherein the added structure does not include a void.

13. The semiconductor device of claim 1, wherein the substrate further includes a cell region positioned adjacent to the contact region, and
the semiconductor device further comprises:
a gate structure extending from the cell region to the contact regions, and including insulating layers and conductive layers alternately stacked;
channel structures positioned in the cell region and extending through the gate structure; and
contact vias positioned in the contact regions and connected to the conductive layers.

14. The semiconductor device of claim 13,
wherein the gate structure further includes a step structure, and
wherein the semiconductor device further comprises an interlayer insulating layer positioned on the step structure.

15. The semiconductor device of claim 14, wherein the contact vias extend through the interlayer insulating layer to be connected to an upper surface of the conductive layers.
